(19) United States
(12) Patent Application Publication
(10) Pub. No.: US 2011/0132450 A1
(43) Pub. Date: Jun. 9, 2011

(54) Back Contact Deposition Using Water-Doped Gas Mixtures

(75) Inventors: Pratima Addepalli, Monroe, MI (US); Sreenivas Jayaraman, Holland, OH (US)

(73) Assignee: First Solar, Inc., Perrysburg, OH (US)

(21) Appl. No.: 12/941,529

(22) Filed: Nov. 8, 2010

Related U.S. Application Data
(60) Provisional application No. 61/259,208, filed on Nov. 8, 2009.

(51) Int. Cl. H01L 31/0216; H01L 31/0296; H01L 31/18

(52) U.S. Cl. 136/256; 438/57; 257/E31.119

(57) ABSTRACT

A method of manufacturing a photovoltaic module may include depositing a semiconductor material adjacent to a substrate; and depositing a back contact material adjacent to the semiconductor material, where depositing the back contact material may include directing a feed gas including hydrogen toward the substrate.

### CLAIM FOR PRIORITY

This application claims priority under 35 U.S.C. §119(e) to U.S. Provisional Patent Application Ser. No. 61/259,208 filed on Nov. 8, 2009, which is hereby incorporated by reference.

### TECHNICAL FIELD

The present invention relates to photovoltaic devices and methods of production.

### BACKGROUND

Photovoltaic devices can include semiconductor materials deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices can also contain one or more transparent conductive oxide layers, which are also often conductors of electrical charge.

### DESCRIPTION OF DRAWINGS

FIG. 1 is a schematic of a photovoltaic module having multiple layers.

FIG. 2 is a schematic of a photovoltaic module having multiple layers.

### DETAILED DESCRIPTION

A method of manufacturing a photovoltaic module can include depositing a semiconductor material adjacent to a substrate and depositing a contact material adjacent to the semiconductor material in the presence of a feed gas including hydrogen, oxygen, water, or a combination thereof toward the substrate.

The method may have various optional features. For example, the contact material may include a molybdenum nitride. The feed gas may include argon gas, nitrogen gas, an argon-nitrogen gas mix, hydrogen, oxygen, water, or any combinations thereof. The method may include doping the feed gas with hydrogen, oxygen, water vapor, or any combinations thereof. The step of depositing a contact material may include physical vapor deposition, chemical vapor deposition, or laser ablation. The method may include depositing a back support on the contact material. The contact material can be a back contact of a thin film photovoltaic device.

In another aspect, a photovoltaic module may include a cadmium telluride layer adjacent to a substrate, and a molybdenum nitride contact comprising at least a trace amount of hydrogen, oxygen, and water.

A photovoltaic device can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power. To preserve and enhance device performance, numerous layers can be positioned above the substrate in addition to the semiconductor window and absorber layers.

Photovoltaic devices can be formed on optically transparent substrates, such as glass. Because glass is not conductive, a transparent conductive oxide (TCO) layer can be deposited between the substrate and the semiconductor bi-layer to serve as a front electrode. Cadmium stannate functions well in this capacity, as it exhibits both high optical transmission and low electrical sheet resistance. A smooth buffer layer can be deposited between the TCO layer and the semiconductor window layer to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in poor performance and degradation of the photovoltaic devices. Thus the TCO can be part of a three-layer stack, which may include, for example, a silicon dioxide barrier layer, a cadmium stannate TCO layer, and a buffer layer. A back contact metal can be deposited onto the semiconductor absorber layer to serve as a back electrode.

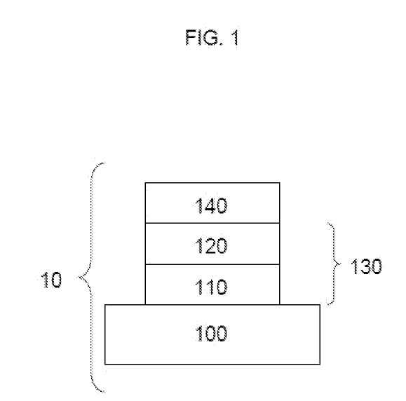

Referring to FIG. 1, a photovoltaic module 10 may include a semiconductor bi-layer 130 deposited over one or more layers 100. One or more layers 100 may include any suitable substrate material, such as a glass, for example, soda-lime glass. One or more layers 100 may also include a transparent conductive oxide layer, which may be part of a transparent conductive oxide stack. Semiconductor bi-layer 130 may include a semiconductor absorber layer 120 on top of a semiconductor window layer 110. Semiconductor absorber layer 120 may include any suitable material, including, for example, a cadmium telluride layer. Semiconductor window layer 110 may include any suitable material, including, for example, a cadmium sulfide layer. Semiconductor bi-layer 130, including semiconductor window layer 110 and semiconductor absorber layer 120, may be deposited using any suitable means, including, for example, vapor transport deposition. A back contact layer 140 may be deposited onto semiconductor absorber layer 120. Back contact layer 140 may include any suitable contact metal or alloy, including, for example, a molybdenum nitride. Back contact layer 140 may be deposited using any suitable means, including, for example, sputtering. Back contact layer 140 may be deposited in any suitable environment, including, for example, in the presence of a gas. For example, a molybdenum nitride, or any other suitable back contact material, may be deposited in the presence of a feed gas, which may include, for example, argon, nitrogen, or an argon-nitrogen gas mix. A dopant may be introduced into the feed gas during the vapor-based deposition process, which process may include, for example, physical vapor deposition, chemical vapor deposition, or laser ablation. For example, hydrogen, oxygen, water, or any combination thereof, may be incorporated within an argon-nitrogen feed gas during deposition of a back contact material (e.g., molybdenum nitride). The resulting module may exhibit improved performance characteristics, including, for example, improved efficiency, increased open circuit voltage, increased fill factor, lower short circuit conductance, as well as increased depletion width. For example, the open circuit voltage can be increased by about one volt. In another example, the efficiency can be improved by about 0.2%.

The water, hydrogen or oxygen content at molybdenum nitride deposition can be between 50 ppm and about 1 atomic percent. In certain circumstances, the water content at molybdenum nitride deposition can be less than 500 ppm, 400 ppm or less, 200 ppm or less, 100 pm or less or 50 ppm or less.

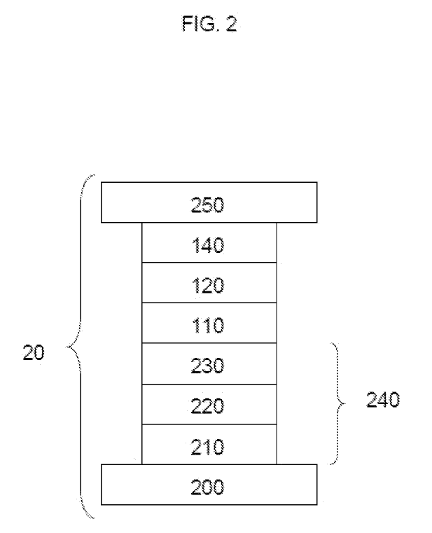

Referring now to FIG. 2, a photovoltaic module 20 may also include a transparent conductive oxide stack 240, which may include a transparent conductive oxide layer 220 deposited onto one or more barrier layers 210. One or more barrier layers 210 may include any suitable barrier material, including, for example, a silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, tin oxide, or combinations thereof. Transparent conductive oxide layer 220 may include a layer of cadmium and tin, and can be of any suitable thickness. For example, transparent conductive oxide layer 220 can have a thickness of about 100 nm to about 1000 nm. Transparent conductive oxide stack 240 may also include a buffer layer 230 deposited on transparent conductive oxide layer 220. Transparent conductive oxide stack 240 can be manufactured using a variety of deposition techniques, including, for example, low pressure chemical vapor deposition, atmospheric pressure chemical vapor deposition, plasma-enhanced chemical vapor deposition, thermal chemical vapor deposition, DC or AC sputtering, spin-on deposition, or spray-pyrolysis. Each deposition layer can be of any suitable thickness, for example, in the range of about 10 to about 5000 A.

A sputtering target can be manufactured by ingot metallurgy. A sputtering target can be manufactured from cadmium, tin, silicon, or aluminum, or combinations or alloys thereof suitable to make individual layers in the stack. For example, the target for a barrier layer can be Si₈₅Al₁₅. The targets for making cadmium stannate layer can be a cadmium and tin alloy in stoichiometrically proper amounts. A sputtering target can be manufactured as a single piece in any suitable shape. A sputtering target can be a tube. A sputtering target can be manufactured by casting a metallic material into any suitable shape, such as a tube.

A sputtering target can be manufactured from more than one piece. A sputtering target can be manufactured from more than one piece of metal, for example, a piece of cadmium and a piece of tin. The cadmium and tin can be manufactured in any suitable shape, such as sleeves, and can be joined or connected in any suitable manner or configuration. For example, a piece of cadmium and a piece of tin can be welded together to form the sputtering target. One sleeve can be positioned within another sleeve.

A sputtering target can be manufactured by powder metallurgy. A sputtering target can be formed by consolidating metallic powder (e.g., cadmium or tin powder) to form the target. The metallic powder can be consolidated in any suitable process (e.g., pressing such as isostatic pressing) and in any suitable shape. The consolidating can occur at any suitable temperature. A sputtering target can be formed from metallic powder including more than one metal powder (e.g., cadmium and tin). More than one metallic powder can be present in stoichiometrically proper amounts.

A sputter target can be manufactured by positioning wire including target material adjacent to a base. For example wire including target material can be wrapped around a base tube. The wire can include multiple metals (e.g., cadmium and tin) present in stoichiometrically proper amounts. The base tube can be formed from a material that will not be sputtered. The wire can be pressed (e.g., by isostatic pressing).

A sputter target can be manufactured by spraying a target material onto a base. Metallic target material can be sprayed by any suitable spraying process, including twin wire arc spraying and plasma spraying. The metallic target material can include multiple metals (e.g., cadmium and tin), present in stoichiometrically proper amounts. The base onto which the metallic target material is sprayed can be a tube.

Following deposition, transparent conductive oxide stack 240 can be annealed using any suitable annealing process. The annealing can occur in the presence of a gas selected to control the atmosphere of the annealing, for example, nitrogen gas. The annealing may be aided by providing an oxygen-depleting or oxygen-reducing environment. Transparent conductive oxide stack 240 can be annealed under any suitable pressure, for example, under reduced pressure, in a low vacuum, or at about 0.01 Pa (10⁻⁴ Torr). Transparent conductive oxide stack 240 can be annealed at any suitable temperature or temperature range. For example, transparent conductive oxide stack 240 can be annealed at about 400 to about 800 C. Transparent conductive oxide stack 240 can be annealed at about 500 to about 700 C. Transparent conductive oxide stack 240 can be annealed at about 550 to about 650 C. Transparent conductive oxide stack 240 can be annealed for any suitable duration. For example, transparent conductive oxide stack 240 can be annealed for more than about 5 minutes, more than about 10 minutes, more than about 15 minutes, or less than about 25 minutes. In continuing reference to FIG. 2, semiconductor bi-layer 130, including semiconductor window layer 110 and semiconductor absorber layer 120, may be deposited onto annealed transparent conductive oxide stack 240. Back contact layer 140 may be deposited onto semiconductor bi-layer 130, and a back support 250 may be deposited thereon. Back support 250 may include any suitable material, including glass, for example, soda-lime glass.

Photovoltaic devices/modules fabricated using the methods and apparatuses discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method of manufacturing a photovoltaic module, the method comprising:
depositing a semiconductor material adjacent to a substrate; and
depositing a contact material adjacent to the semiconductor material in the presence of a feed gas comprising hydrogen, oxygen or water toward the substrate.

2. The method of claim 1, wherein the contact material comprises a molybdenum nitride.

3. The method of claim 1, wherein the feed gas comprises argon gas.

4. The method of claim 1, wherein the feed gas comprises nitrogen gas.

5. The method of claim 1, wherein the feed gas comprises an argon-nitrogen gas mix.

6. The method of claim 1, wherein the feed gas comprises oxygen.

7. The method of claim 1, wherein the feed gas comprises water.

8. The method of claim 1, further comprising doping the feed gas with hydrogen.

9. The method of claim 1, further comprising doping the feed gas with oxygen.

10. The method of claim 1, further comprising doping the feed gas with water vapor.

11. The method of claim 1, wherein the step of depositing a back contact material comprises physical vapor deposition.

12. The method of claim 1, wherein the step of depositing a back contact material comprises chemical vapor deposition.

13. The method of claim 1, wherein the step of depositing a back contact material comprises laser ablation.

14. The method of claim 1, further comprising depositing a back support on the back contact material.

15. A photovoltaic module comprising:
a cadmium telluride layer adjacent to a substrate; and
a molybdenum nitride back contact comprising at least a trace amount of hydrogen, oxygen, or water.
